(19) United States
(12) Patent Application Publication
(10) Pub. No.: US 2024/0009763 A1
(43) Pub. Date: Jan. 11, 2024

(54) LASER PROCESSING MACHINE

(71) Applicant: DISCO CORPORATION, Tokyo (JP)

(72) Inventor: Yuta YOSHIDA, Tokyo (JP)

(21) Appl. No.: 18/347,723

(22) Filed: Jul. 6, 2023

(30) Foreign Application Priority Data
Jul. 8, 2022 (JP) 2022-110440

(51) Int. Cl. B23K 26/06; B23K 26/064

(52) U.S. Cl. CPC B23K 26/0626; B23K 26/064

(57) ABSTRACT

A laser beam irradiation unit of a laser processing machine includes a laser oscillator, an image-forming element that focuses, on a workpiece, a laser beam emitted from the laser oscillator, and a phase modulation unit arranged between the laser oscillator and the image-forming element and configured to cause a phase difference in the laser beam such that the laser beam forms an intensity distribution along a Gaussian distribution in an X-axis direction parallel to each street set on the workpiece and forms an intensity distribution along a top-hat profile at an image-forming point in a Y-axis direction as a width direction of the each street set on the workpiece.

### BACKGROUND OF THE INVENTION

### Field of the Invention

The present invention relates to a laser processing machine.

### Description of the Related Art

As a method for singulating a workpiece such as a semiconductor wafer, blade dicing that causes a high-speed rotating, thin disk-shaped blade to cut into the workpiece is in common use. Meanwhile, in recent years, laser dicing that performs dicing of a workpiece by applying a laser beam along projected dicing lines (streets) has also been developed and adopted. In this laser dicing, there has been proposed a technology that adjusts lines to be processed, by modifying the profile of an image to be formed by a laser beam on a workpiece, through a mask (see, for example, JP 2010-089094A).

### SUMMARY OF THE INVENTION

The use of the method described in JP 2010-089094A makes it possible to apply processing in a desired profile to a workpiece, but on the other hand, blocks most of a laser beam by a mask, thereby leading to a problem that the energy permitted to contribute to the processing is reduced.

The present invention therefore has as an object thereof the provision of a laser processing machine which can process a workpiece with a laser beam of a desired profile without attenuation of its energy that can contribute to the processing.

In accordance with a first aspect of the present invention, there is provided a laser processing machine for applying a laser beam to a workpiece that has a plurality of intersecting streets, along the streets to apply processing to the workpiece. The laser processing machine includes a holding table that holds the workpiece, a laser beam irradiation unit that applies the laser beam to the workpiece held on the holding table, an X-axis direction moving unit that carries out relative processing feed of the workpiece and an image-forming point of the laser beam in an X-axis direction, and a Y-axis direction moving unit that carries out relative indexing feed of the workpiece and the image-forming point of the laser beam in a Y-axis direction orthogonal to the X-axis direction. The laser beam irradiation unit includes a laser oscillator, an image-forming element that focuses, on the workpiece, the laser beam emitted from the laser oscillator, and a phase modulation unit arranged between the laser oscillator and the image-forming element and configured to cause a phase difference in the laser beam such that the laser beam forms an intensity distribution along a Gaussian distribution in the X-axis direction parallel to each street set on the workpiece and forms an intensity distribution along a top-hat profile at the image-forming point in the Y-axis direction as a width direction of the each street set on the workpiece.

Preferably, the phase modulation unit may be a phase plate capable of adjusting a phase of light, and the phase plate may include a recessed portion or a protruding portion formed such that the intensity distribution is formed along the top-hat profile in the Y-axis direction as the width direction of the each street set on the workpiece.

In accordance with a second aspect of the present invention, there is provided a laser processing machine for applying a laser beam to a workpiece that has a plurality of intersecting streets, along the streets to apply processing to the workpiece. The laser processing machine includes a holding table that holds the workpiece, a laser beam irradiation unit that applies the laser beam to the workpiece held on the holding table, an X-axis direction moving unit that carries out relative processing feed of the workpiece and an image-forming point of the laser beam in an X-axis direction, and a Y-axis direction moving unit that carries out relative indexing feed of the workpiece and the image-forming point of the laser beam in a Y-axis direction orthogonal to the X-axis direction. The laser beam irradiation unit includes a laser oscillator, an image-forming element that focuses, on the workpiece, the laser beam emitted from the laser oscillator, and a first phase plate and a second phase plate arranged between the laser oscillator and the image-forming element and configured to cause a phase difference in the laser beam such that the laser beam forms an intensity distribution along a Gaussian distribution in the X-axis direction parallel to each street set on the workpiece and forms an intensity distribution along a top-hat profile at the image-forming point in the Y-axis direction as a width direction of the each street set on the workpiece. The first phase plate and the second phase plate are configured to be movable relative to each other, and an amount of relative movement between the first phase plate and the second phase plate is adjusted on the basis of a beam diameter of the laser beam incident to the first phase plate and the second phase plate.

Preferably, the first phase plate and the second phase plate may each be configured to have a large thickness region and a small thickness region, the first phase plate and the second phase plate may be arranged such that the large thickness region of the first phase plate faces the small thickness region of the second phase plate and the small thickness region of the first phase plate faces the large thickness region of the second phase plate, and the top-hat profile may be adjusted in width by an adjustment of an overlapping width of the small thickness region of the first phase plate and the small thickness region of the second phase plate.

The present invention realizes the hat-top profile by changing the intensity distribution of the laser beam from the Gaussian distribution to an airy disk pattern with the phase modulation unit unlike the related art, that is, without using a mask that attenuates the energy of the laser beam by 60% to 70%, and then allowing the laser beam to form an image, and therefore can perform laser processing of the workpiece with a laser beam of a desired profile without attenuation of its energy that can contribute to the laser processing.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view illustrating a configuration example of a laser processing machine according to a first embodiment of the present invention;

FIG. 2 is a cross-sectional view illustrating a configuration example of a laser beam irradiation unit of FIG. 1;

FIG. 3 is a graph illustrating an example of an intensity distribution of a laser beam emitted by a laser oscillator of FIG. 2;

FIG. 4 is a perspective view illustrating a phase modulation unit of FIG. 2;

FIG. 5 is a top view illustrating the phase modulation unit of FIG. 2;

FIG. 6 is a graph illustrating an example of an intensity distribution of the laser beam formed by the laser beam irradiation unit of FIG. 2;

FIG. 7 is a graph illustrating an example of an intensity distribution of another laser beam formed by the laser beam irradiation unit of FIG. 2;

FIG. 8 is a top view illustrating an example of an intensity profile of the laser beam of FIG. 7 formed by the laser beam irradiation unit of FIG. 2;

FIG. 9 is a top view illustrating an example of an image-forming point of the laser beam of FIG. 7 formed by the laser beam irradiation unit of FIG. 2;

FIG. 10 is a cross-sectional view illustrating a configuration example of a laser beam irradiation unit of a laser processing machine according to a second embodiment of the present invention;

FIG. 11 is a perspective view illustrating a phase modulation unit of FIG. 10;

FIG. 12 depicts a bottom view and a top view illustrating the phase modulation unit of FIG. 10;

FIG. 13 is a graph illustrating an example of an intensity distribution of a laser beam formed by a laser beam irradiation unit of a laser processing machine according to a modification;

FIG. 14 is a graph illustrating an example of an intensity profile of the laser beam formed by the laser beam irradiation unit of the laser processing machine according to the modification;

FIG. 15 is a graph illustrating another example of the intensity distribution of the laser beam formed by the laser beam irradiation unit of the laser processing machine according to the modification; and

FIG. 16 is a graph illustrating another example of the intensity profile of the laser beam formed by the laser beam irradiation unit of the laser processing machine according to the modification.

### DETAILED DESCRIPTION OF THE PREFERRED EMBODIMENTS

With reference to the attached drawings, a description will be made in detail regarding embodiments of the present invention. However, the present invention shall not be limited by details that will be described in the subsequent embodiments. The elements of configurations that will hereinafter be described include those readily conceivable to persons skilled in the art and substantially the same ones. Further, the configurations that will hereinafter be described can be combined appropriately. Moreover, various omissions, replacements, and modifications of configurations can be made without departing from the spirit of the present invention.

### First Embodiment

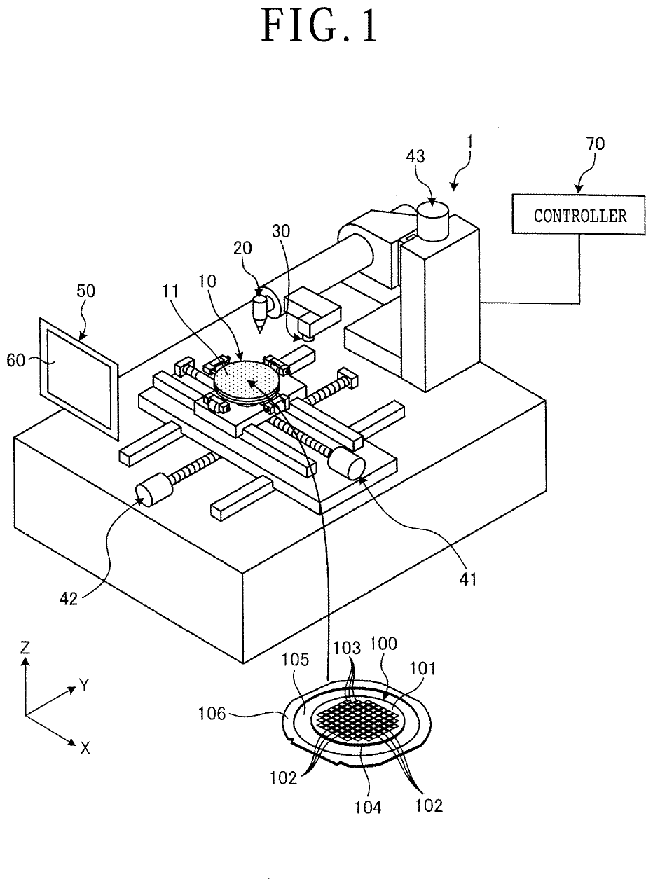

A laser processing machine 1 according to a first embodiment of the present invention will be described with reference to FIGS. 1 through 9. FIG. 1 is a perspective view illustrating a configuration example of the laser processing machine 1 according to the first embodiment. As illustrated in FIG. 1, the laser processing machine 1 according to the first embodiment includes a holding table 10, a laser beam irradiation unit 20, an imaging unit 30, an X-axis direction moving unit 41, a Y-axis direction moving unit 42, a Z-axis direction moving unit 43, a display unit 50, an input unit 60, and a controller 70.

As illustrated in FIG. 1, a workpiece 100 to be processed by the laser processing machine 1 according to the first embodiment is, for example, a disk-shaped semiconductor wafer, an optical device wafer, or the like which is made of a base material such as silicon, sapphire, silicon carbide (SiC), gallium arsenide, or glass. The workpiece 100 has chip-size devices 103 formed in regions defined by a plurality of streets 102 formed in a grid pattern on a planar front surface 101 as illustrated in FIG. 1. In the first embodiment, the workpiece 100, as illustrated in FIG. 1, includes a self-adhesive tape 105 bonded to a back surface 104 on a side opposite to the front surface 101, and an annular frame 106 attached to an outer edge portion of the self-adhesive tape 105, but not limited to the foregoing in the present invention. In the present invention, the workpiece 100 may also be a rectangular package substrate, a ceramic plate, a glass plate, or the like having a plurality of devices sealed with resin.

The holding table 10 includes a disk-shaped frame body with a recessed portion formed therein and a disk-shaped suction portion fitted in the recessed portion. The suction portion of the holding table 10 is formed from a porous ceramic or the like having a number of pores, and is connected to a vacuum suction source (not illustrated) via a vacuum suction channel (not illustrated). The suction portion of the holding table 10 has an upper surface which, as illustrated in FIG. 1, acts as a holding surface 11. When the workpiece 100 is placed on the holding surface 11, the holding surface 11 holds the placed workpiece 100 by suction under a negative pressure introduced from the vacuum suction source. In the first embodiment, the workpiece 100 is placed on the holding surface 11 with the front surface 101 directed upward, and the holding surface 11 holds the placed workpiece 100 by suction from a side of the back surface 104 via the self-adhesive tape 105. The holding surface 11 and an upper surface of the frame body of the holding table 10 are arranged on the same plane, and lie horizontally with an XY plane that is a horizontal plane.

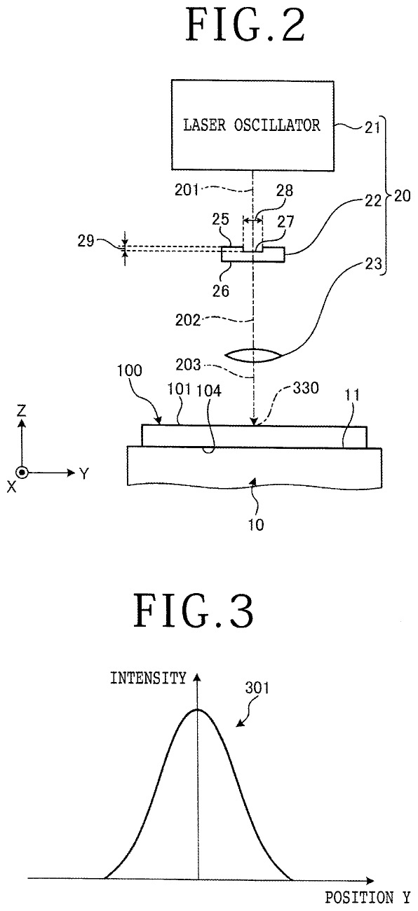

The holding table 10 is disposed movably in an X-axis direction, which is parallel to a horizontal direction, by the X-axis direction moving unit 41, and is also disposed movably in a Y-axis direction, which is parallel to the horizontal direction and is orthogonal to the X-axis direction, by the Y-axis direction moving unit 42. The holding table 10 is moved along the X-axis direction and the Y-axis direction by the X-axis direction moving unit 41 and the Y-axis direction moving unit 42, respectively, so that the workpiece 100 held on the holding table 10 is moved in the X-axis direction and the Y-axis direction, respectively, relative to an image-forming point 330 (see FIG. 2) of a laser beam 203 (see FIG. 2) formed by the laser beam irradiation unit 20 and to the imaging unit 30. The holding table 10 is disposed rotatably about a Z-axis, which is parallel to a vertical direction and is orthogonal to the XY plane, by a rotary drive source (not illustrated). The holding table 10 is appropriately rotated by the rotary drive source to adjust its direction about the Z-axis such that the streets 102 in desired one of the directions of the workpiece 100 held on the holding surface 11 become parallel to the X-axis direction.

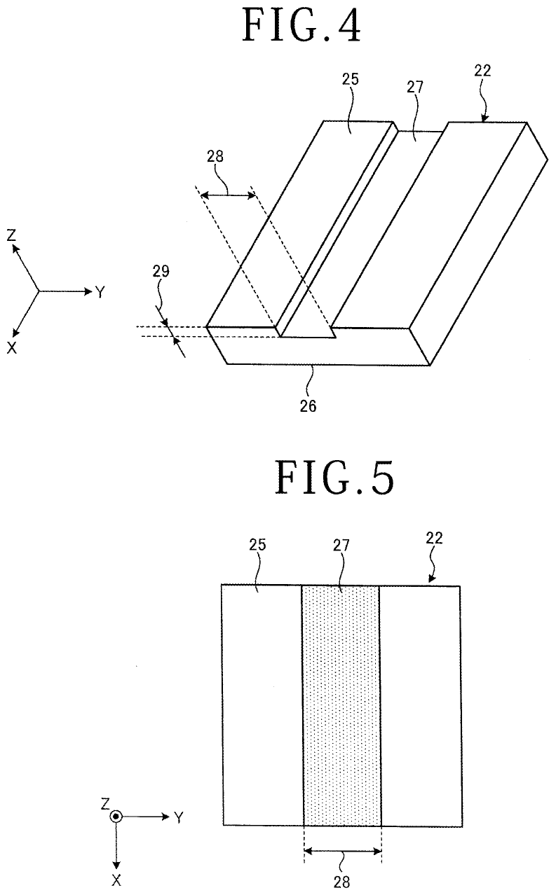

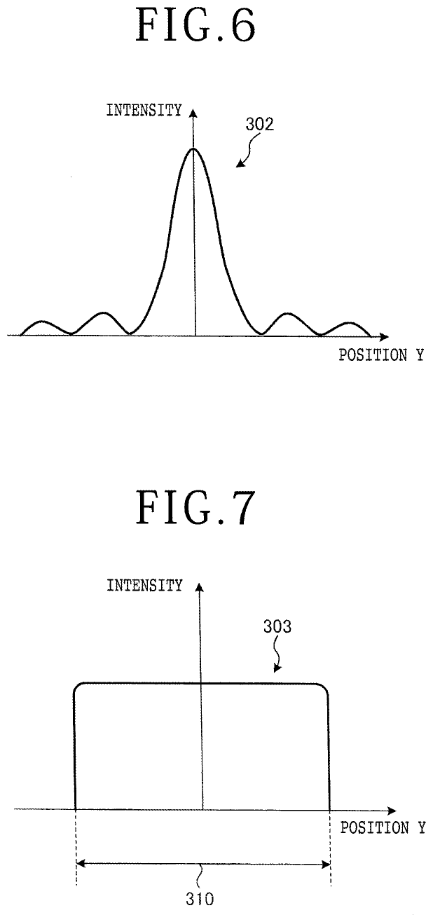

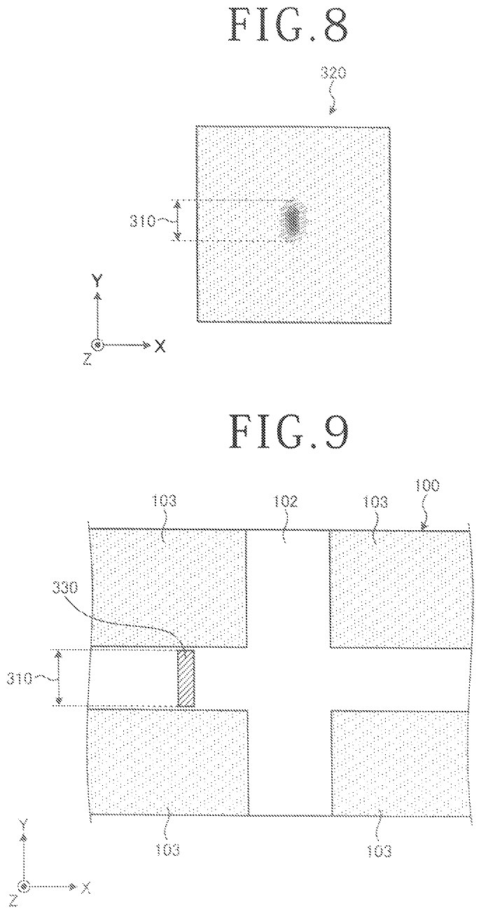

FIG. 2 is a cross-sectional view illustrating a configuration example of the laser beam irradiation unit 20 of FIG. 1. FIG. 3 is a graph illustrating an example of an intensity distribution of a laser beam 201 emitted by a laser oscillator 21 of FIG. 2. FIGS. 4 and 5 are a perspective view and a top view, respectively, which illustrate a phase modulation unit 22 of FIG. 2. FIGS. 6 and 7 are graphs illustrating examples of intensity distributions of a laser beam 202 and the laser beam 203 both formed by the laser beam irradiation unit 20 of FIG. 2. FIG. 8 is a top view illustrating an example of an intensity profile of the laser beam 203 formed by the laser beam irradiation unit 20 of FIG. 2. FIG. 9 is a top view illustrating an example of the image-forming point 330 of the laser beam 203 formed by the laser beam irradiation unit 20 of FIG. 2. It is to be noted that, in the graphs illustrated in FIGS. 3, 6, and 7, the abscissas each indicate the position in the Y-axis direction, which is a width direction of the streets 102, as plotted using an optical path as an origin, and the ordinates indicate the intensities of the laser beams 201, 202, and 203, respectively. It is also to be noted that, in a frame of FIG. 8, a horizontal direction in the plane of the paper sheet represents the position in the X-axis direction parallel to the streets 102, a vertical direction in the plane of the paper sheet represents the position in the Y-axis direction, the dot density represents the intensity of the laser beam 203, and a higher dot density indicates a higher intensity of the laser beam 203.

The laser beam irradiation unit 20, as illustrated in FIG. 2, has the laser oscillator 21, the phase modulation unit 22, and an image-forming element 23. The laser oscillator 21 emits the laser beam 201 of a wavelength having absorptivity for the workpiece 100, along a Z-axis direction toward the workpiece 100 held on the holding table 10. The laser beam 201 forms an intensity distribution 301, centering at the optical path, along a Gaussian distribution in both the X-axis direction and, as illustrated in FIG. 3, the Y-axis direction. The laser beam 201 is in a pulse form, for example, of a 5 mm beam diameter and a 355 nm wavelength in the first embodiment, but not limited to this in the present invention.

The phase modulation unit 22, as illustrated in FIG. 2, is arranged between the laser oscillator 21 and the image-forming element 23 on the optical path of the laser beam 201 emitted from the laser oscillator 21. As illustrated in FIGS. 2, 4, and 5, the phase modulation unit 22 is a phase plate capable of adjusting the phase of light. The phase plate is formed in a plate shape sufficiently larger than the beam diameter of the laser beam 201 in both the X-axis direction and the Y-axis direction, and has a pair of a first surface 25 and a second surface 26 parallel to the XY plane and orthogonal to the optical path of the laser beam 201 emitted from the laser oscillator 21. As the phase modulation unit 22, one obtained, for example, by forming synthetic quartz which has a refractive index of 1.449 into a plate shape of a 6 mm thickness is used, for example. The first surface 25 is directed upward in the Z-axis direction, and the second surface 26 is directed downward in the Z-axis direction.

In the phase modulation unit 22, a recessed portion 27 is formed in the first surface 25 such that an intensity distribution 302 along such an airy disk pattern as illustrated in FIG. 6 is formed in the Y-axis direction. The recessed portion 27 is specifically a groove which extends along the X-axis direction over a length sufficiently greater than the beam diameter of the laser beam 201, is symmetrical with respect to a plane that includes the optical path of the laser beam 201, and is parallel to an X-axis, and which has a quadrilateral (rectangular) shape in a cross-section along a YZ plane. The recessed portion 27 has a width 28 in the Y-axis direction, which is dimensioned to allow the laser beam 201 to straddle the recessed portion 27 in a width direction, specifically, has a predetermined dimension narrower than the beam diameter of the laser beam 201. The width 28 of the recessed portion 27 is determined on the basis of the beam diameter of the laser beam 201 and a desired value of a width 310 (see FIG. 7) of a top-hat profile of a below-described intensity distribution 303 (see FIG. 7) of the laser beam 203 to be applied to the workpiece 100.

The recessed portion 27 has a depth 29 in the Z-axis direction, which has a predetermined dimension capable of causing a predetermined phase difference (for example, a phase difference of π/2) in the laser beam 201, which passes through the phase modulation unit 22, by a difference in the thickness of the laser beam 201 in the direction of its optical path, the difference being equivalent to the depth 29 formed by the recessed portion 27. The depth 29 of the recessed portion 27 is determined according to the refractive index of a base material of the phase modulation unit 22, and is, for example, approximately 395 nm if the base material of the phase modulation unit 22 is synthetic quartz.

Owing to the formation of the recessed portion 27 of the shape as mentioned above, the phase modulation unit 22 induces no modulation in phase on the laser beam 201 incident from the first surface 25 because the laser beam 201 does not straddle a step formed by the recessed portion 27, in the X-axis direction in which the recessed portion 27 extends. In the Y-axis direction in which the step is formed by the recessed portion 27, on the other hand, the laser beam 201 straddles the step formed by the recessed portion 27. A phase difference is therefore caused by the step of the recessed portion 27 to induce a modulation in phase, so that the intensity distribution 302 along the airy disk pattern can be formed. This allows the phase modulation unit 22 to form the intensity distribution 301 along the Gaussian distribution like the laser beam 201 in the X-axis direction, and also to cause the phase difference in the laser beam 201 incident from the first surface 25 such that the intensity distribution 302 is formed along the airy disk pattern in the Y-axis direction.

When the laser beam 201 is incident from the first surface 25, the phase modulation unit 22 emits, from the second surface 26, the laser beam 202 with the intensity distribution 301 formed along the Gaussian distribution in the X-axis direction and the intensity distribution 302 formed along the airy disk pattern in the Y-axis direction. It is to be noted that, as will be mentioned below, the intensity distribution 302 along the airy disk pattern is converted, as a result of the formation of an image through the image-forming element 23, into the intensity distribution 303 along the top-hat profile at the image-forming point 330 as illustrated in FIG. 7.

The phase modulation unit 22 includes the recessed portion 27 formed in the first surface 25 in the first embodiment. Without being limited to this configuration in the present invention, a protruding portion may be formed on the first surface 25. It is to be noted that the protruding portion in this alternative extends in the X-axis direction, and its cross-sectional shape along the YZ plane is rectangular, has a width of a dimension similar to that of the width 28 of the recessed portion 27, and has a height of a dimension similar to that of the depth 29 of the recessed portion 27. Even if the protruding portion is formed instead of the recessed portion 27 as described above, the phase modulation unit 22 induces a modulation in phase similar to that in the formation of the recessed portion 27. When the laser beam 201 is incident from the first surface 25, the laser beam 202 is therefore emitted from the second surface 26 with the intensity distribution 301 formed along the Gaussian distribution in the X-axis direction and the intensity distribution 302 formed along the airy disk pattern in the Y-axis direction. Further, the phase modulation unit 22 is not limited to these configurations in the present invention, and the recessed portion 27 or the protruding portion may be formed in or on the second surface 26 instead of the first surface 25, or may be formed in or on each of the first surface 25 and the second surface 26.

Further, in the phase modulation unit 22, the depth 29 of the recessed portion 27 may be set to be the same as the plate thickness of the phase modulation unit 22. In other words, the phase modulation unit 22 may be formed in a shape such that a gap of a width similar to the width 28 in the Y-axis direction is formed extending through in the direction of the optical path of the laser beam 201 and the laser beam 201 passes the phase plate on sides of only its outer peripheries in the Y-axis direction.

The image-forming element 23 focuses the laser beam 202 emitted from the laser oscillator 21 and modulated in phase by the phase modulation unit 22, and forms an image on the workpiece 100 held on the holding table 10, thereby forming the image-forming point 330. As described above, the image-forming element 23 focuses the laser beam 202 having the intensity distribution 301 formed along the Gaussian distribution in the X-axis direction and the intensity distribution 302 formed along the airy disk pattern in the Y-axis direction, thereby converting the laser beam 202 into the laser beam 203 having the intensity distribution 301 formed along the Gaussian distribution in the X-axis direction and the intensity distribution 303 formed along the top-hat profile in the Y-axis direction as illustrated in FIG. 7.

The width 310 of the top-hat profile of the intensity distribution 303 can be set at a desired value equivalent to the width of processed grooves, which are to be formed along the streets 102, by appropriately setting the width 28 of the recessed portion 27.

The laser beam 203 formed through the image-forming element 23 forms an intensity profile 320 having a breadth equivalent to the width 310 of the intensity distribution 303 in the Y-axis direction as illustrated in FIG. 8. When this laser beam 203 is applied to each street 102 on the workpiece 100, the image-forming point 330 of a profile equivalent to the intensity profile 320 is formed as illustrated in FIG. 9.

As described above, the laser beam irradiation unit 20 emits, from the laser oscillator 21, the laser beam 201 with the intensity distribution 301 formed along the Gaussian distribution, forms the laser beam 203 with the intensity distribution 301 formed along the Gaussian distribution in the X-axis direction and the intensity distribution 303 formed along the top-hat profile in the Y-axis direction through the phase modulation unit 22 and the image-forming element 23, and applies the laser beam 203 to the workpiece 100 held on the holding table 10, to form the image-forming point 330 on the workpiece 100.

The image-forming element 23 included in the laser beam irradiation unit 20 is disposed movably in the Z-axis direction by the Z-axis direction moving unit 43. When the image-forming element 23 included in the laser beam irradiation unit 20 is moved in the Z-axis direction by the Z-axis direction moving unit 43, the image-forming point 330 of the laser beam 203, the image-forming point 330 being formed by the laser beam irradiation unit 20, and the imaging unit 30 are moved in the Z-axis direction relative to the workpiece 100 held on the holding table 10.

The imaging unit 30 includes an imaging device that images the front surface 101 and streets 102 of the workpiece 100 held on the holding table 10, processed grooves formed in the front surface 101, and the like. The imaging device is, for example, a charge-coupled device (CCD) imaging device or a complementary metal oxide semiconductor (CMOS) imaging device. In the first embodiment, the imaging unit 30 is arranged adjacent to the laser beam irradiation unit 20 in such a manner as to be movable integrally with the image-forming element 23 included in the laser beam irradiation unit 20.

The imaging unit 30 images the workpiece 100 which is held on the holding table 10 and has not yet been subjected to laser processing, to acquire an image to be used in performing a positional registration, in other words, an alignment or the like between the workpiece 100 and the laser beam irradiation unit 20 (image-forming point 330), and outputs the acquired image to the controller 70. In addition, the imaging unit 30 also images the workpiece 100 which is held on the holding table 10 and has been subjected to the laser processing, and acquires an image to be used in automatically checking if the processed grooves fall within the streets 102 and any large chipping or the like has occurred, in other words, in performing a kerf check, and outputs the acquired image to the controller 70.

The X-axis direction moving unit 41 carries out relative processing feed, in the X-axis direction, of the workpiece 100 held on the holding table 10 and the image-forming point 330 of the laser beam 203 to be applied by the laser beam irradiation unit 20. The Y-axis direction moving unit 42 carries out relative indexing feed, in the Y-axis direction, of the workpiece 100 held on the holding table 10 and the image-forming point 330 of the laser beam 203 to be applied by the laser beam irradiation unit 20. The Z-axis direction moving unit 43 carries out relative movement, in the Z-axis direction, of the workpiece 100 held on the holding table 10 and the image-forming point 330 of the laser beam 203 to be applied by the laser beam irradiation unit 20. The X-axis direction moving unit 41, the Y-axis direction moving unit 42, and the Z-axis direction moving unit 43 detect the relative positions in the X-axis direction, the Y-axis direction, and the Z-axis direction of the holding table 10 and the laser beam irradiation unit 20, and output the detected relative positions to the controller 70.

The display unit 50 is disposed on a cover (not illustrated) of the laser processing machine 1 with a side of a display screen directed outward, and displays a screen of setting of irradiation conditions and the like for the laser beam 203 in the laser processing machine 1, a screen presenting the results of processing, including an alignment, autofocusing, an automatic light adjustment, a kerf check, and the like, such that an operator can visually recognize them. The display unit 50 includes a liquid crystal display device or the like. The display unit 50 is provided with the input unit 60 to be used when the operator inputs command information and the like regarding various operations of the laser processing machine 1, laser beam irradiation conditions, the display of images, and so on. The input unit 60 with which the display unit 50 is provided is configured by at least one of a touch panel incorporated in the display unit 50, a keyboard, or the like.

The controller 70 controls operations of the individual elements of the laser processing machine 1 to make the laser processing machine 1 perform laser processing or the like by applying the laser beam 203 to the workpiece 100. The controller 70 includes a computer system in the first embodiment. This computer system has a computation processing unit having a microprocessor such as a central processing unit (CPU), a storage device having a memory such as a read only memory (ROM) or a random access memory (RAN), and an input/output interface device. The computation processing unit of the controller 70 performs computation processing according to a computer program stored in the storage device of the controller 70, and outputs control signals to the individual elements of the laser processing machine 1 via the input/output interface device of the controller 70 to control the laser processing machine 1.

A description will be made of one example of operation processing by the laser processing machine 1 according to the first embodiment. The laser processing machine 1 first performs a positional registration, in other words, an alignment between the workpiece 100 and the laser beam irradiation unit 20 (image-forming point 330) by holding the workpiece 100 on the holding surface 11 of the holding table 10, rotating the holding table 10 with the rotary drive source to make an adjustment such that the streets 102 in desired one of the directions of the workpiece 100 on the holding table 10 become parallel to the X-axis direction, and capturing, with the imaging unit 30, an image of the workpiece 100 on the holding table 10.

The laser processing machine 1 next subjects the workpiece 100 to laser processing (what is generally called ablation processing) along each street 102 with the laser beam 203 by carrying out, with the X-axis direction moving unit 41, processing feed of the workpiece 100 held on the holding table 10, relative to the image-forming point 330 of the laser beam 203 along the street 102 while applying, from the laser beam irradiation unit 20, the laser beam 203 with the intensity distribution 301 formed along the Gaussian distribution in the X-axis direction and the intensity distribution 303 formed along the top-hat profile in the Y-axis direction.

The laser processing machine 1 according to the first embodiment, which is configured as described above, realizes the top-hat profile at the image-forming point 330 by converting the intensity distribution of the laser beam 201 from the Gaussian distribution into the airy disk pattern through the phase modulation unit 22 (phase plate) without using a mask which attenuates the energy of a laser beam by 60% to 70%, unlike the related art, and then focusing the resulting laser beam 203. The laser processing machine 1 according to the first embodiment therefore exhibits advantageous effects in that the workpiece 100 can be subjected to laser processing with a laser beam of a desired profile without attenuating its energy that contributes to the laser processing.

Further, the laser processing machine 1 according to the first embodiment can suppress damage to the devices 103 and an uneven wear of a cutting blade during blade dicing as a subsequent step by setting the intensity distribution in the top-hat profile in the width direction (Y-axis direction) of each street 102 formed on the workpiece 100, and can also effectively perform removal of, for example, a test element group (TEG) chip as an evaluation device which is present on the street 102, by converting the intensity distribution into the Gaussian distribution in the processing feed direction (X-axis direction) along the street 102.

As the recessed portion 27 or the protruding portion is formed such that the phase modulation unit 22 forms the airy disk pattern in the Y-axis direction, the laser processing machine 1 according to the first embodiment can suitably realize the irradiation of the laser beam 203 with the intensity distribution formed as the Gaussian distribution in the X-axis direction and also the intensity distribution formed in the top-hat profile in the Y-axis direction.

### Second Embodiment

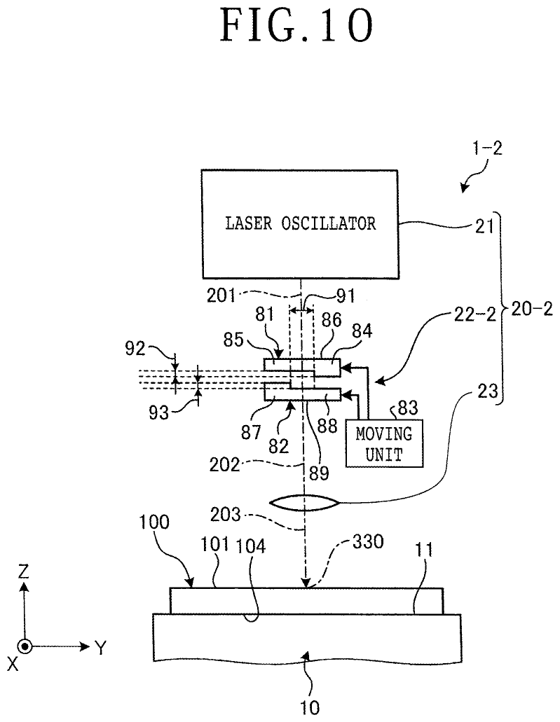

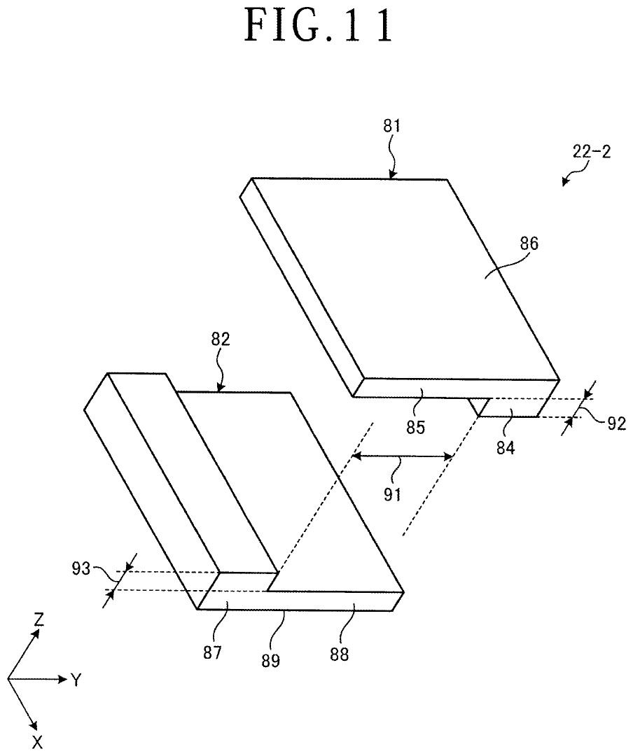

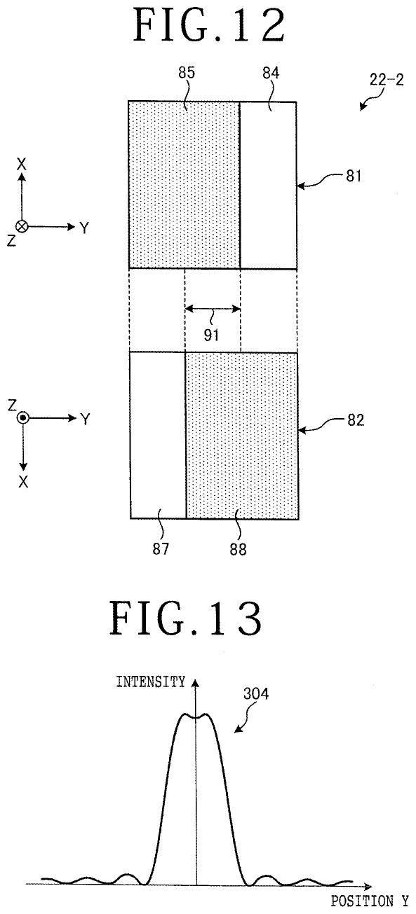

A laser processing machine 1-2 according to a second embodiment of the present invention will be described with reference to FIGS. 10 to 12. FIG. 10 is a cross-sectional view illustrating a configuration example of a laser beam irradiation unit 20-2 of the laser processing machine 1-2 according to the second embodiment. FIG. 11 is a perspective view illustrating a phase modulation unit 22-2 of FIG. 10. FIG. 12 depicts a bottom view and a top view illustrating the phase modulation unit 22-2 of FIG. 10. Described more specifically, FIG. 12 illustrates a bottom view of a first phase plate 81 on an upper side of the paper sheet, and also illustrates a top view of a second phase plate 82 on a lower side of the paper sheet. In FIGS. 10 to 12, portions identical to those of the first embodiment are identified by the same reference numerals, and their description is omitted.

The laser processing machine 1-2 according to the second embodiment is different from the laser processing machine 1 according to the first embodiment in that the laser beam irradiation unit 20 has been changed to the laser beam irradiation unit 20-2. The laser beam irradiation unit 20-2 is different from the laser beam irradiation unit 20 in that the phase modulation unit 22 has been changed to the phase modulation unit 22-2. With regard to the rest of the configurations, the laser processing machine 1-2 according to the second embodiment is similar to the laser processing machine 1 according to the first embodiment.

When a laser beam 201 is incident from a first surface 86, the phase modulation unit 22-2, similarly to the phase modulation unit 22, emits, from a second surface 89, a laser beam 202 with an intensity distribution 301 formed along a Gaussian distribution in the X-axis direction and an intensity distribution 302 formed along an airy disk pattern in the Y-axis direction.

As illustrated in FIG. 10, the phase modulation unit 22-2 has a first phase plate 81, a second phase plate 82, and a moving unit 83. As illustrated in FIGS. 10, 11, and 12, the first phase plate 81 is formed in a plate shape, and has a large thickness region 84 and a small thickness region 85. The first phase plate 81 has the first surface 86 parallel to the XY plane, and in a surface on a side opposite to the first surface 86, a step of a depth 92 is formed in the Z-axis direction along a boundary between the region 84 and the region 85. As illustrated in FIGS. 10, 11, and 12, the second phase plate 82 is formed in a plate shape, and has a large thickness region 87 and a small thickness region 88. The second phase plate 82 has the second surface 89 parallel to the XY plane, and in a surface on a side opposite to the second surface 89, a step of a depth 93 is formed in the Z-axis direction along a boundary between the region 87 and the region 88. The region 85 and the region 88 have a greater width in the Y-axis direction than that of the region 84 and the region 87, respectively. As the first phase plate 81 and the second phase plate 82, those which are each formed, for example, with a material similar to and in a plate shape of a size and a thickness substantially similar to those of the phase modulation unit 22 in the first embodiment are used. The depth 92 and the depth 93 are set to be equal in the second embodiment, and are approximately a half of the depth 29 of the first embodiment.

As illustrated in FIGS. 10, 11, and 12, the first phase plate 81 and the second phase plate 82 are arranged such that the region 84 of the first phase plate 81 faces the region 88 of the second phase plate 82, the region 87 of the second phase plate 82 faces the region 85 of the first phase plate 81, and there is a region in which the region 85 of the first phase plate 81 and the region 88 of the second phase plate 82 overlap in the Z-axis direction. The first phase plate 81 is arranged above the second phase plate 82 such that the first surface 86 is directed upward in the Z-axis direction and the stepped surface on the side opposite to the first surface 86 faces, in the Z-axis direction, the stepped surface on the side opposite to the second surface 89 of the second phase plate 82. The second phase plate 82 is arranged below the first phase plate 81 such that the second surface 89 is directed downward in the Z-axis direction and the stepped surface on the side opposite to the second surface 89 faces, in the Z-axis direction, the stepped surface on the side opposite to the first surface 86 of the first phase plate 81.

The moving unit 83 supports the first phase plate 81 and the second phase plate 82 movably relative to each other in the Y-axis direction. The moving unit 83 relatively moves the first phase plate 81 and the second phase plate 82 in the Y-axis direction such that the boundary (step) between the region 84 and the region 85 and the boundary (step) between the region 87 and the region 88 are symmetrical with respect to a plane which includes an optical path of the laser beam 201 and is parallel to the X-axis, in other words, such that the region in which the region 85 of the first phase plate 81 and the region 88 of the second phase plate 82 overlap in the Z-axis direction includes the optical path of the laser beam 201 and is symmetrical with respect to the plane parallel to the X-axis. When the moving unit 83 moves the first phase plate 81 in a direction toward the optical path of the laser beam 201, for example, the moving unit 83 moves the second phase plate 82 in a direction toward the optical path of the laser beam 201. When the moving unit 83 moves the first phase plate 81 in a direction away from the optical path of the laser beam 201, on the other hand, the moving unit 83 moves the second phase plate 82 in a direction away from the optical path of the laser beam 201. The moving unit 83 is controlled by the controller 70.

In the phase modulation unit 22-2, a width (in other words, an overlapping width) 91 in the Y-axis direction of the region in which the region 85 of the first phase plate 81 and the region 88 of the second phase plate 82 overlap in the Z-axis direction is determined on the basis of the beam diameter of the laser beam 201 incident to the first phase plate 81 and the second phase plate 82 and a desired value of the width 310 of the top-hat profile of the intensity distribution 303 of the laser beam 203 to be applied to the workpiece 100, and on the basis of the width 91, the amount of the relative movement between the first phase plate 81 and the second phase plate 82 by the moving unit 83 is determined. The phase modulation unit 22-2 can adjust the width 310 of the top-hat profile of the intensity distribution 303 of the laser beam 203 to be applied to the workpiece 100, to the desired value by adjusting the width 91 through an adjustment of the amount of the relative movement between the first phase plate 81 and the second phase plate 82 by the moving unit 83. The width 91 is adjusted, for example, to be approximately equal to the width 28 of the recessed portion 27 of the first embodiment.

As an alternative, the phase modulation unit 22-2 may also be set such that the small thickness region 85 of the first phase plate 81 has a thickness of zero and the small thickness region 88 of the second phase plate 82 has a thickness of zero. In other words, the phase modulation unit 22-2 may be configured in such a form that the first phase plate 81 includes only the large thickness region 84, the second phase plate 82 includes only the large thickness region 87, and the laser beam 201 passes the phase plates (regions 84 and 87) on sides of only their outer peripheries in the Y-axis direction.

As described above, the laser processing machine 1-2 according to the second embodiment is different from the laser processing machine 1 according to the first embodiment in that the phase modulation unit 22 has been changed to the phase modulation unit 22-2. When the laser beam 201 is incident from the first surface 86, the phase modulation unit 22-2, similarly to the phase modulation unit 22, emits, from the second surface 89, the laser beam 202 with the intensity distribution 301 formed along the Gaussian distribution in the X-axis direction and the intensity distribution 302 formed along the airy disk pattern in the Y-axis direction. The laser processing machine 1-2 according to the second embodiment therefore exhibits advantageous effects similar to those of the laser processing machine 1 according to the first embodiment.

Further, the phase modulation unit 22-2 has the first phase plate 81 and the second phase plate 82, which are movable relative to each other in the Y-axis direction. The laser processing machine 1-2 according to the second embodiment is therefore adaptable to various beam diameters of the laser beam 201 emitted from the laser oscillator 21, by adjusting the width (in other words, the overlapping width) 91 in the Y-axis direction of the region in which the small thickness region 85 of the first phase plate 81 and the small thickness region 88 of the second phase plate 82 overlap in the Z-axis direction, through the adjustment of the amount of the relative movement between the first phase plate 81 and the second phase plate 82. It is hence possible for the laser processing machine 1-2 according to the second embodiment to perform laser processing by changing the beam diameter and also to compensate for deteriorations, individual differences, and the like of the laser oscillator 21.

### Modification

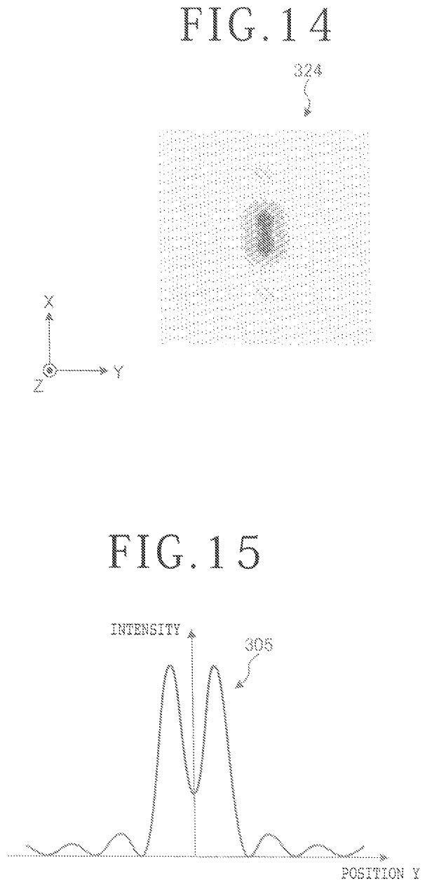

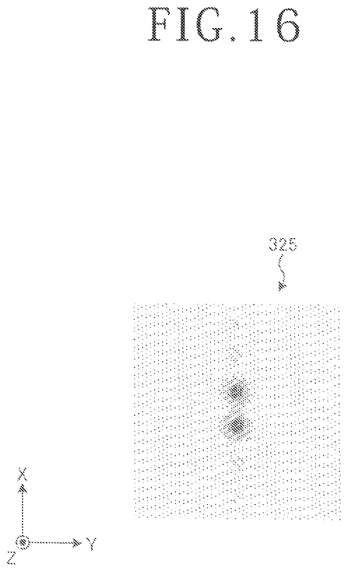

A laser processing machine 1 or 1-2 according to a modification of the present invention will be descried with reference to FIGS. 13 to 16. FIGS. 13 and 14 are graphs illustrating examples of an intensity distribution and an intensity profile of a laser beam 203 formed by a laser beam irradiation unit 20 or 20-2 of the laser processing machine 1 or 1-2 according to the modification. The abscissas and the ordinates in FIGS. 13 and 15 are similar to those in FIGS. 3, 6, and 7. The horizontal directions, the vertical directions, and the dot densities in FIGS. 14 and 16 are similar to those in FIG. 8. In FIGS. 13 to 16, portions identical to those of the first embodiment or the second embodiment are identified by the same reference numerals, and their description is omitted.

If the various widths, depths, and the like of the phase modulation unit 22 or 22-2 of the laser beam irradiation unit 20 or 20-2 are set such that the laser beam 203 of the intensity distribution 303 and the intensity profile 320 is formed when the beam diameter of the laser beam 201 is targeted at 0.9 mm, setting of the beam diameter of the laser beam 201 at a value greater than the target, that is, 1.4 mm, forms an intensity profile 325 with a peak separated into two in the Y-axis direction as illustrated in FIGS. 15 and 16. On the other hand, setting of the beam diameter of the laser beam 201 at a value greater even slightly than that target, that is, 1.0 mm, forms an intensity profile 324 with a peak spreading slightly in the Y-axis direction as illustrated in FIGS. 13 and 14. The laser processing machine 1 or 1-2 according to the modification may subject the workpiece 100 to laser processing by the laser beam 203 that forms the intensity distribution 304 or 305 and intensity profile 324 or 325 as described above.

It is to be noted that the present invention shall not be limited to the above-described embodiments. In other words, the present invention can be practiced with various changes or modifications within the scope not departing from the spirit of the present invention. For example, the phase modulation units 22 and 22-2 are configured by the single phase plate and the two phase plates, respectively. However, the present invention is not limited to the use of such a single phase plate or such two phase plates, and may use a spatial optical modulator that adjusts optical characteristics of the laser beam 201 emitted from the laser oscillator 21, that is, a liquid crystal on silicon-spatial light modulator (what is generally called an LCOS-SLM).

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A laser processing machine for applying a laser beam to a workpiece that has a plurality of intersecting streets, along the streets to apply processing to the workpiece, the laser processing machine comprising:
a holding table that holds the workpiece;
a laser beam irradiation unit that applies the laser beam to the workpiece held on the holding table;
an X-axis direction moving unit that carries out relative processing feed of the workpiece and an image-forming point of the laser beam in an X-axis direction; and
a Y-axis direction moving unit that carries out relative indexing feed of the workpiece and the image-forming point of the laser beam in a Y-axis direction orthogonal to the X-axis direction,
wherein the laser beam irradiation unit includes
a laser oscillator,
an image-forming element that focuses, on the workpiece, the laser beam emitted from the laser oscillator, and
a phase modulation unit arranged between the laser oscillator and the image-forming element and configured to cause a phase difference in the laser beam such that the laser beam forms an intensity distribution along a Gaussian distribution in the X-axis direction parallel to each street set on the workpiece and forms an intensity distribution along a top-hat profile at the image-forming point in the Y-axis direction as a width direction of the each street set on the workpiece.

2. The laser processing machine according to claim 1,
wherein the phase modulation unit is a phase plate, and
the phase plate includes a recessed portion or a protruding portion formed such that the intensity distribution is formed along the top-hat profile in the Y-axis direction as the width direction of the each street set on the workpiece.

3. A laser processing machine for applying a laser beam to a workpiece that has a plurality of intersecting streets, along the streets to apply processing to the workpiece, the laser processing machine comprising:
a holding table that holds the workpiece;
a laser beam irradiation unit that applies the laser beam to the workpiece held on the holding table;
an X-axis direction moving unit that carries out relative processing feed of the workpiece and an image-forming point of the laser beam in an X-axis direction; and
a Y-axis direction moving unit that carries out relative indexing feed of the workpiece and the image-forming point of the laser beam in a Y-axis direction orthogonal to the X-axis direction,
wherein the laser beam irradiation unit includes
a laser oscillator,
an image-forming element that focuses, on the workpiece, the laser beam emitted from the laser oscillator, and
a first phase plate and a second phase plate arranged between the laser oscillator and the image-forming element and configured to cause a phase difference in the laser beam such that the laser beam forms an intensity distribution along a Gaussian distribution in the X-axis direction parallel to each street set on the workpiece and forms an intensity distribution along a top-hat profile at the image-forming point in the Y-axis direction as a width direction of the each street set on the workpiece, and
the first phase plate and the second phase plate are configured to be movable relative to each other, and an amount of relative movement between the first phase plate and the second phase plate is adjusted on a basis of a beam diameter of the laser beam incident to the first phase plate and the second phase plate.

4. The laser processing machine according to claim 3,
wherein the first phase plate and the second phase plate are each configured to have a large thickness region and a small thickness region,
the first phase plate and the second phase plate are arranged such that the large thickness region of the first phase plate faces the small thickness region of the second phase plate and the small thickness region of the first phase plate faces the large thickness region of the second phase plate, and
the top-hat profile is adjusted in width by an adjustment of an overlapping width of the small thickness region of the first phase plate and the small thickness region of the second phase plate.
